(19) United States
(12) Patent Application Publication
(10) Pub. No.: US 2020/0211518 A1
(43) Pub. Date: Jul. 2, 2020

(54) SMART PLAYGROUND WITH USER ACTIVATED FEATURES AND RELATED METHODS

(71) Applicant: FROG HOLDINGS, LLC, Winter Park, FL (US)

(72) Inventors: MICHAEL VOLL, WINTER PARK, FL (US); EDWARD BRITTAIN VOLL, WINTER PARK, FL (US)

(21) Appl. No.: 16/728,267

(22) Filed: Dec. 27, 2019

Related U.S. Application Data
(60) Provisional application No. 62/785,759, filed on Dec. 28, 2018.

(51) Int. Cl. G10H 1/00; H01L 41/113; H04R 1/02; A63B 9/00

(52) U.S. Cl. CPC G10H 1/0008; H01L 41/1132; A63B 2009/006; A63B 9/00; H04R 1/028

(57) ABSTRACT

A playground structure may include a body, a piezoelectric sensor carried by the body and configured to detect a touch input on adjacent portions of the body, and an output device configured to generate audio indicators. The playground structure may include a controller coupled to the output device and the piezoelectric sensor and configured to selectively change the audio indicators based upon the touch input.

### RELATED APPLICATION

This application is based upon prior filed copending Application No. 62/785,759 filed Dec. 28, 2018, the entire subject matter of which is incorporated herein by reference in its entirety.

### TECHNICAL FIELD

The present disclosure relates to the field of recreational structures, and, more particularly, to playground structures with active features and related methods.

### BACKGROUND

Parks and activity centers are ubiquitous in American culture. Indeed, these areas are common in urban areas and suburban areas, and have a history extending more than a century in urban areas. Common park recreational devices include climbing structures, such as a jungle-gym, slides, merry-go-rounds, seesaws, zip lines, and balance beams.

Most park recreational devices are static. In other words, the park recreational device does not change nor interact with the user. In some approaches, the park recreational device includes a mechanical interface for users to interact with, such as a spinning wheel, but these mechanical interfaces are quite limited and are physical driven by the user.

### SUMMARY

Generally, a playground structure may include a body, a piezoelectric sensor carried by the body and configured to detect a touch input on adjacent portions of the body, and an output device configured to generate audio indicators. The playground structure may include a controller coupled to the output device and the piezoelectric sensor and configured to selectively change the audio indicators based upon the touch input.

In particular, the body may have a major surface, and a blind passageway extending inwardly from the major surface. The piezoelectric sensor may be carried within the blind passageway. The piezoelectric sensor may include a fastener comprising a head, and a stud extending from the head and into the body within the blind passageway, and a piezoelectric sensor circuit board coupled to the head of the fastener.

In some embodiments, the fastener may comprise a metallic material, and the piezoelectric sensor may include a magnetic body. The piezoelectric sensor circuit board may be between the magnetic body and the head of the fastener. The body may comprise a longitudinal path coupled to the blind passageway. The playground structure may comprise a wired connection extending in the longitudinal path and coupled between the piezoelectric sensor circuit board and the controller.

Also, the piezoelectric sensor circuit board may comprise a wireless transceiver configured to wirelessly communicate with the controller. The output device may comprise an audiovisual output device configured to generate audiovisual indicators, and the controller may be configured to change the audiovisual indicators based upon the touch input. The output device may be configured to generate the audio indicators comprising musical instrumental audio indicators. The playground structure may also further comprise an ultrasonic sensor carried by the body, coupled to the controller, and configured to detect the touch input on the adjacent portions of the body.

Another aspect is directed to a climbing frame playground structure. The climbing frame playground structure may include a body comprising a plurality of elongate segments coupled together, and a plurality of piezoelectric sensors. Each piezoelectric sensor may be carried by a respective elongate segment of the body and configured to detect a touch input on adjacent portions of the respective elongate segment. The climbing frame playground structure may include an output device configured to generate audio indicators. The climbing frame playground structure may comprise a controller coupled to the output device and the plurality of piezoelectric sensors and configured to selectively change the audio indicators based upon the touch input.

Yet another aspect is directed to a method for making a playground structure. The method may include positioning a piezoelectric sensor to be carried by a body and configured to detect a touch input on adjacent portions of the body, positioning an output device to generate audio indicators and coupling a controller to the output device and the piezoelectric sensor and configured to selectively change the audio indicators based upon the touch input.

### BRIEF DESCRIPTION OF THE DRAWINGS

FIG. 1 is a schematic diagram of a first example embodiment of a playground structure, according to the present disclosure.

FIGS. 2A-2H are schematic diagrams of varying example embodiments of the playground structure, according to the present disclosure.

FIG. 3 is a schematic front side of beams from the body from the example embodiment of the playground structure of FIG. 1.

FIG. 4 is a schematic front side of a single beam from the body from the example embodiment of the playground structure of FIG. 1.

FIG. 5 is a schematic cross-section view of a sensor in the example embodiment of the playground structure of FIG. 3 along line 5-5.

FIG. 6 is a schematic diagram of a climbing frame playground structure, according to the present disclosure.

FIG. 7 is a schematic cross-section view of a piezoelectric sensor in the example embodiment of the climbing frame playground structure of FIG. 6.

FIG. 8 is a schematic diagram of another embodiment of the piezoelectric sensor circuit board from the example embodiment of the climbing frame playground structure of FIG. 6.

### DETAILED DESCRIPTION

The present disclosure will now be described more fully hereinafter with reference to the accompanying drawings, in which several embodiments of the invention are shown. This present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art. Like numbers refer to like elements throughout, and base 100 reference numerals are used to indicate similar elements in alternative embodiments.

Children often learn and experience the world through play. Among other positive results, play can be educational, relaxing, and therapeutic. Existing and new play structures can be enhanced by integrating systems that identify particular interactions causing command and management of devices as a function of specific interactions. Such enhancements could encourage more interaction, use, experimentation, and learning.

The present invention relates to play structures and playground equipment. More particularly, the invention relates to a system that is capable of detecting human interaction with playground structures through the use of sensors and creating output signals correlated to the specific interaction identified.

The present invention may be used on public playgrounds where interaction with play structures causes command and management of devices as a function of specific interactions. To further this example, movement up or down a slide could be identified causing note or groups of notes corresponding to a musical instrument to be amplified through a speaker or group of speakers surrounding the slide or play area containing the slide.

The present invention concerns a system which recognizes interactions made directly or indirectly with, on, or near play structures; this system comprises: associating a sensor or multiple sensors connected with said play structure; creating an input signal generated by said interactions with the play structure; segmenting said signals to obtain a group or groups of signal segments and values processed from said signal; processing said signal segments identifying characteristics and features of said group of signal segments to identify patterns and/or metric functions of said interactions; supplying a specific output signal correlated to the specific interaction identified. Further, the present invention concerns a system to recognize interactions with play structures and generate said output signal.

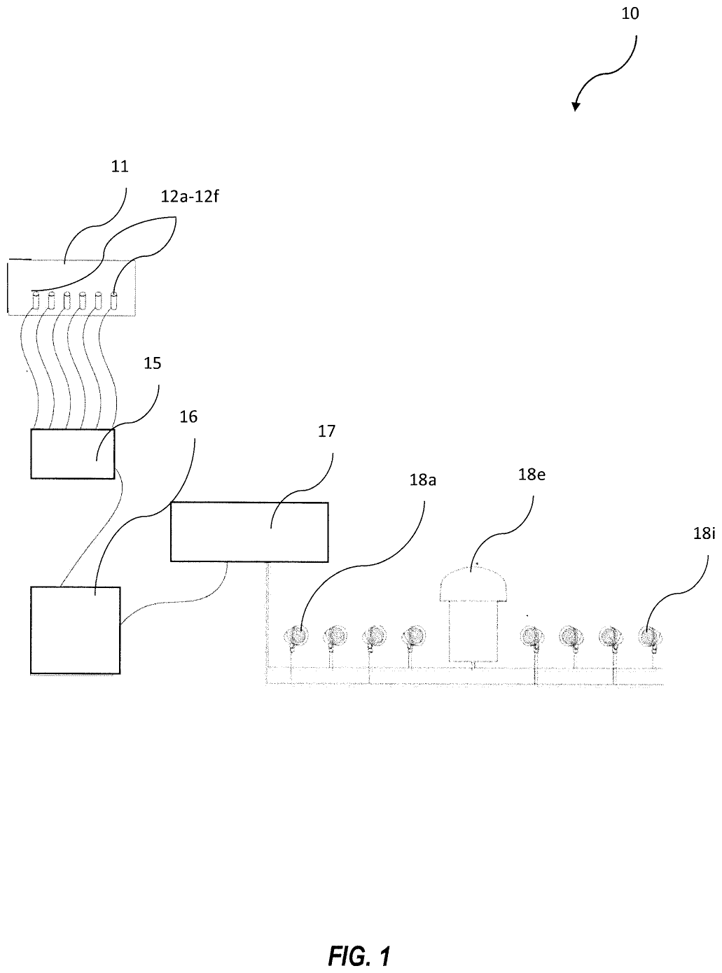

Referring now to FIG. 1, a playground structure 10 according to the present disclosure is now described. The playground structure 10 is configured to sense user interaction through a plurality of sensors 12a-12f within a body 11 of the playground structure. The user interaction may comprise any physical action made directly, indirectly, or by means of another element by the user on, in, with, or near the body 11 of the playground structure 10. For example, the user interaction may comprise can be a tap, a touch, a scratch, a knock, a hit, a swipe, a movement, and/or other type of interaction made at various intervals, intensities, and/or durations.

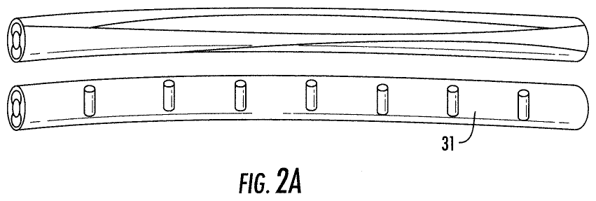

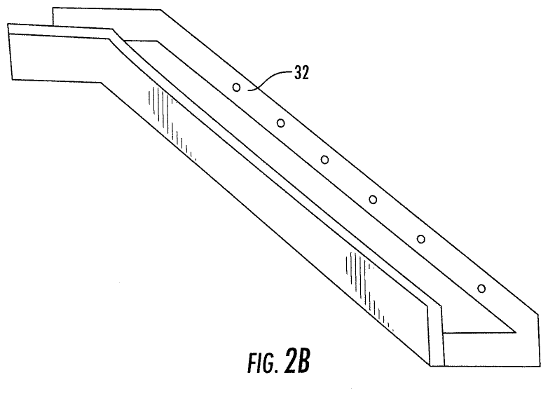

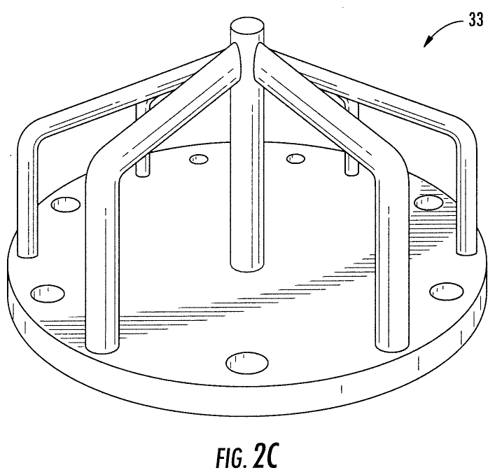

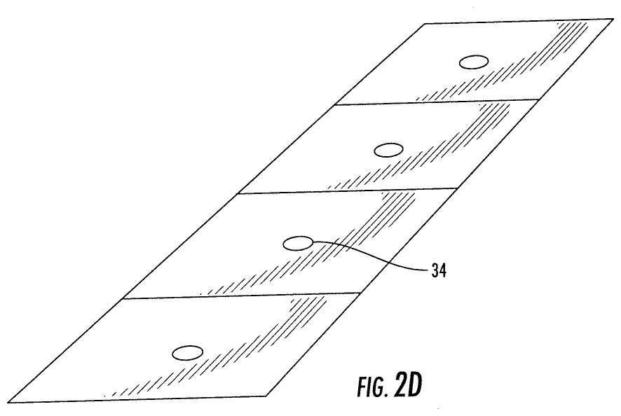

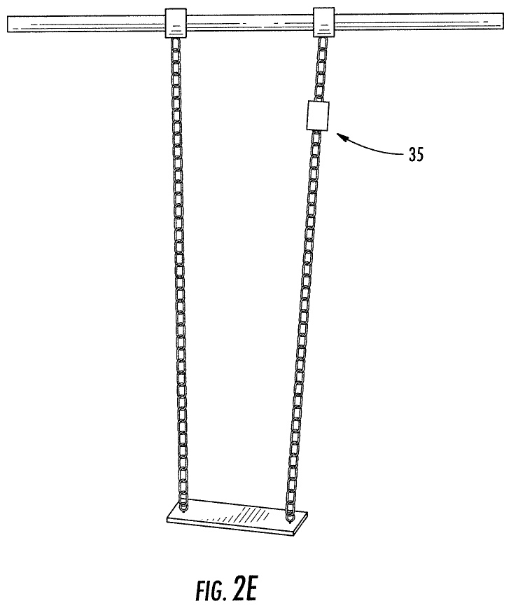

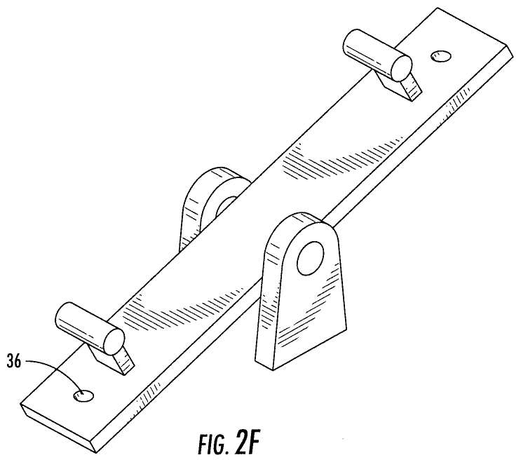

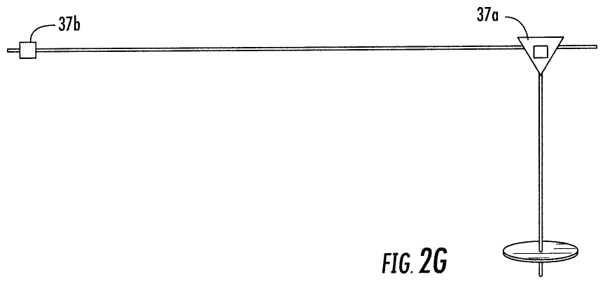

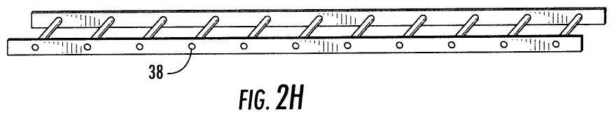

As shown in FIG. 2A-2H, the body 11 of the playground structure 10 can include a wooden log/beam (FIG. 2A), a slide (FIG. 2B), a merry-go-round (FIG. 2C), a side-walk (FIG. 2D), a swing (FIG. 2E), a seesaw (FIG. 2F), a zip-line (FIG. 2G), and/or monkey bars (FIG. 2H). The playground structure 10 illustratively comprises a plurality of sensors 12a-12f within the body 11 to detect interactions with the playground structure. The plurality of sensors 12a-12f may sense a variety of characteristics, such as, light, vibration, resistance, acceleration, tilt, pitch, speed, velocity, distance, and/or other measurements of interactions.

In one embodiment, the plurality of sensors 12a-12f is designed to detect vibration, and may be recessed into a wooden log 31 to detect interaction with the wooden log. In the embodiment where the plurality of sensors 12a-12f is configured to detect movement, distance, and/or velocity, the plurality of sensors may be recessed or attached to a slide 32 to detect interaction with the slide. In the embodiment where the plurality of sensors 12a-12f is configured to detect presence, movement, distance, and/or velocity, the plurality of sensors may be recessed or attached to a merry-go-round 33 to detect interaction with the merry-go-round. In the embodiment where the plurality of sensors 12a-12f is configured to detect light and/or vibration, the plurality of sensors may be recessed in a sidewalk 34 to detect interaction with the sidewalk.

In the embodiment where the plurality of sensors 12a-12f is configured to detect acceleration, tilt, pitch, speed, and/or velocity, the plurality of sensors may be attached to a swing 35 to detect interaction with the swing. In the embodiment where the plurality of sensors 12a-12f is configured to detect acceleration, tilt, pitch, speed, and/or velocity, the plurality of sensors may be recess attached or attached to a seesaw 36 to detect interaction with the swing.

In the embodiment where the plurality of sensors 12a-12f is configured to detect acceleration, vibration, tilt, pitch, speed, and/or velocity, the plurality of sensors may be attached to a zip line 37a-37b to detect interaction with the zip line. In the embodiment where the plurality of sensors 12a-12f is configured to detect vibration, the plurality of sensors may be recessed into or attached to monkey bars 38 to detect interaction with the monkey bars.

In some embodiments, the plurality of sensors 12a-12f is configured to be coupled to a processing component 14 of the present invention through a wired or wireless connection 13. Input signals may be received by the processing component 14, and may be analyzed to identify and classify specific interactions and generate an output signal. The output signal(s) generated may be mapped to generate a specific audio output or series of outputs through a wired or wireless connection 15 and may be processed by an audio system 16 and amplified 17 through a speaker or series of speakers 18a-18i.

The user interactions detected by sensors within the body 11 of the playground structure 10 may be mapped to generate output signals that trigger different notes, series of notes, or combination of notes of a musical instrument to be amplified and played through a speaker or series of speakers surrounding the play structure.

Referring now again to FIG. 1, a playground structure 10 is now described. The playground structure 10 illustratively includes a body having at least one exposed surface. As will be appreciated, the body may take on may form factors, such as the exemplary form factors shown in FIGS. 2A-2H, and/or at least one of a slide-form factor, a jungle-gym-form factor, a climbing-form factor, a balancing-form factor, a merry-go round-form factor, a crawl tube-form factor, a motion/spinning-form factor, and a swing-form factor.

The playground structure 10 illustratively includes a sensor 12a-12f carried by the body and configured to detect a touch input on the at least one exposed surface. In some embodiments, the sensor 12a-12f comprises a piezoelectric sensor configured to detect pressure on the at least one exposed surface. In other embodiments, the sensor comprises a motion detector sensor, or an image sensor. The sensor 12a-12f is configured to detect use of the playground structure 10.

The playground structure 10 illustratively comprises an audio output 18a-18i (e.g. a speaker) spaced apart from the body, and a controller 14 coupled to the audio output and the sensor and configured to generate an audio sound feature when the touch input is detected. In some embodiments, the speaker 18a-18i may be integrated within the body. The controller 14 may comprise a processing unit, such as an Arduino microcontroller, as available from the Arduino AG of San Jose, Calif.

The audio sound feature is configurable for each body form-factor. For example, when the body has a jungle-gym form factor, the playground structure 10 includes respective sensors 12a-12f for each step of the jungle-gym. In some embodiments, user interaction with each step would create a distinct sound, such as a musical note with distinct pitch. In particular, the notes may increase in frequency as the user climbs upward. In some embodiments, the plurality of steps may be configured to provide a virtual instrument wherein each note from the musical scale is mapped to a portion/step of the jungle-gym.

For example, when the body has a slide form factor, the playground structure 10 includes a plurality of sensors 12a-12f positioned along the length of the slide. In other words, the user movement along the slide is detected and a plurality sound features could be generated. In particular, when the user uses the slide, the controller 14 is configured to generate a melodic increasing or decreasing scale.

In some embodiments, the playground structure 10 includes non-auditory effects, such a light effects. For example, the controller 14 may be configured to activate the light effects based upon the sensed signal from the sensors 12a-12f.

In another exemplary application, when the body has a jungle-gym form factor, the playground structure 10 includes respective sensors 12a-12f for a single step of the jungle-gym. In this application, the single step or beam of the jungle-gym would provide a virtual instrument with a partial or complete scale of notes. Indeed, in one advantageous embodiment, each beam of the jungle-gym would be mapped to a scale of notes for a different instrument, permitting a plurality of users to simultaneously play the virtual instruments.

Another aspect is directed to a method for making a playground structure 10. The method includes forming a body having at least one exposed surface, and positioning a sensor 12a-12f to be carried by the body and configured to detect a touch input on the at least one exposed surface. The method includes positioning an audio output carried by the body, and coupling a controller to the audio output and the sensor and configured to generate an audio sound feature when the touch input is detected.

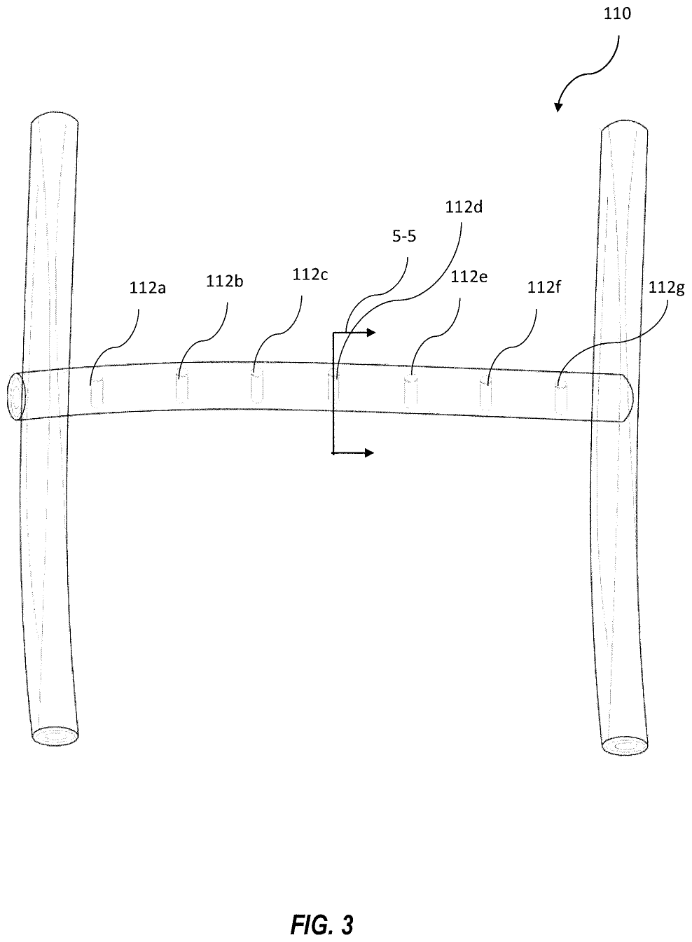

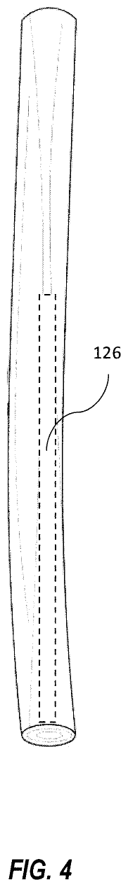

Referring now to FIGS. 3-5, an exemplary embodiment of the playground structure 110 is now described. In this embodiment, the form-factor of the body is a jungle-gym with a plurality of actual timber beam segments. Of course, in other embodiments, the beam segments may comprise artificial materials, such as a polymer or composite polymer.

In this embodiment, the playground structure 110 illustratively includes a plurality of sensors 112a-112g for each beam segment. Each sensor 112a-112g illustratively includes a piezoelectric sensor 122, a magnet 123 coupled thereto, and a plurality of cables 120a-120b coupled with the controller 114. Each beam segment illustratively includes a cable conduit 126 extending between respective ends of the beam.

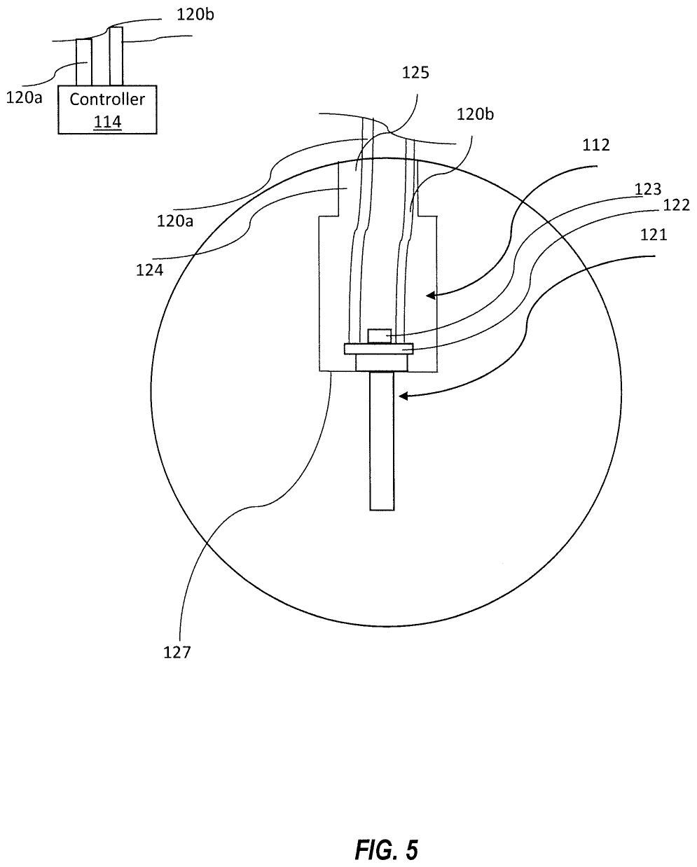

Each beam segment illustratively includes a plurality of recesses 124 within and each recess being accessible via an opening 125. As perhaps best seen in FIG. 5, the respective sensor 112 is positioned within the recess 124. Each sensor includes a fastener 121 (e.g. a lag bolt with threading) anchored in a distal wall 127 of the recess 124. The piezoelectric sensor 122 is positioned adjacent a head of the fastener 121, and the magnet 123 is configured to sandwich the piezoelectric sensor between the head of the fastener. In this embodiment, the fastener 121 comprises a ferromagnetic material. As will be appreciated, the magnet 123 provides a secure pressure fit for the piezoelectric sensor 122. Advantageously, this embodiment is readily installed in many materials, including the illustrated actual organic timber material.

During typical use, when a user is touching the beam segment, the vibration from the touch is transmitted to the fastener 121, and then to the piezoelectric sensor 122. Via the plurality of cables 120a-120b, the sensed signal is transmitted to the controller 114. As evident, the cable conduit 126 is sized to fit the respective cables from the plurality of sensors 112a-112g. The controller 114 is configured to generate a one or more sound effects for each sensed touch input.

In another embodiment, not shown, the fastener 121 is replaced with another fastening arrangement. The fastening arrangement may comprise a ferromagnetic piece, and an adhesive layer coupling the ferromagnetic piece to the distal wall 127.

In yet another embodiment, the sensor 112 may omit the plurality of cables 120a-120b for a wireless interface (e.g. Bluetooth, WiFi, ZigBee, or other low power radio frequency (RF)). For example, the sensor 112 may comprise a wireless transmitter configured to transmit the sensed signal to the controller 114. In these wireless embodiments, the sensor 112 would include a battery source, providing an entirely wireless package.

In another embodiment, the sensor 112 may comprise a modular single piece package. In particular, the sensor 112 would comprise a housing carrying the piezoelectric sensor 122 and other needed circuitry (e.g. wireless transmitter). In this embodiment, housing would be fitted into the recess 124, and fixed rigidly therein, for example, using adhesive, an interface fit, or a pressure fit.

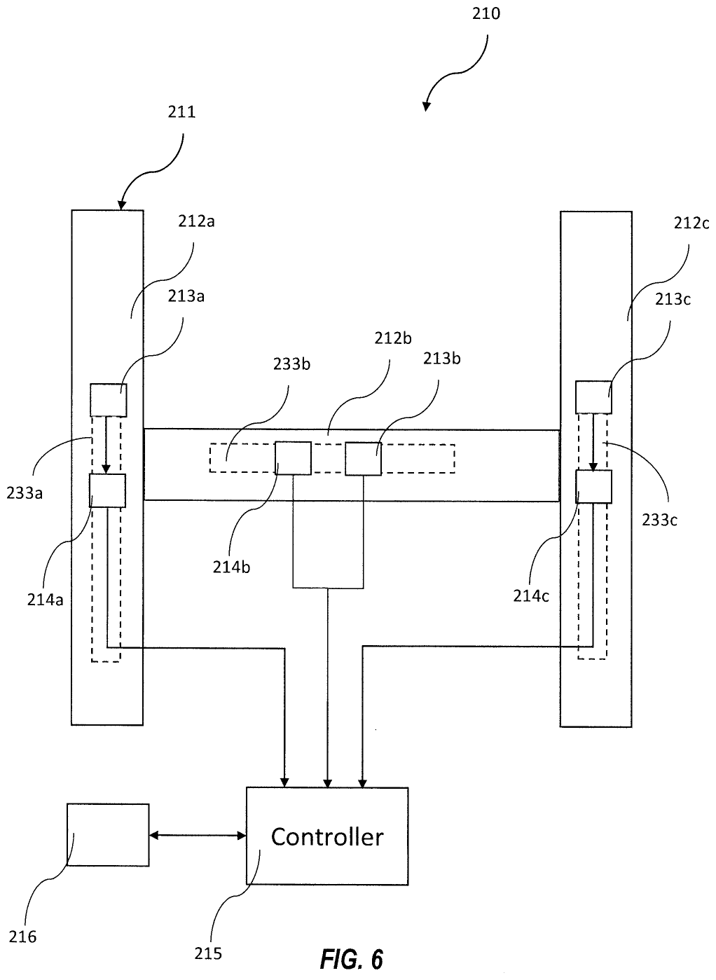

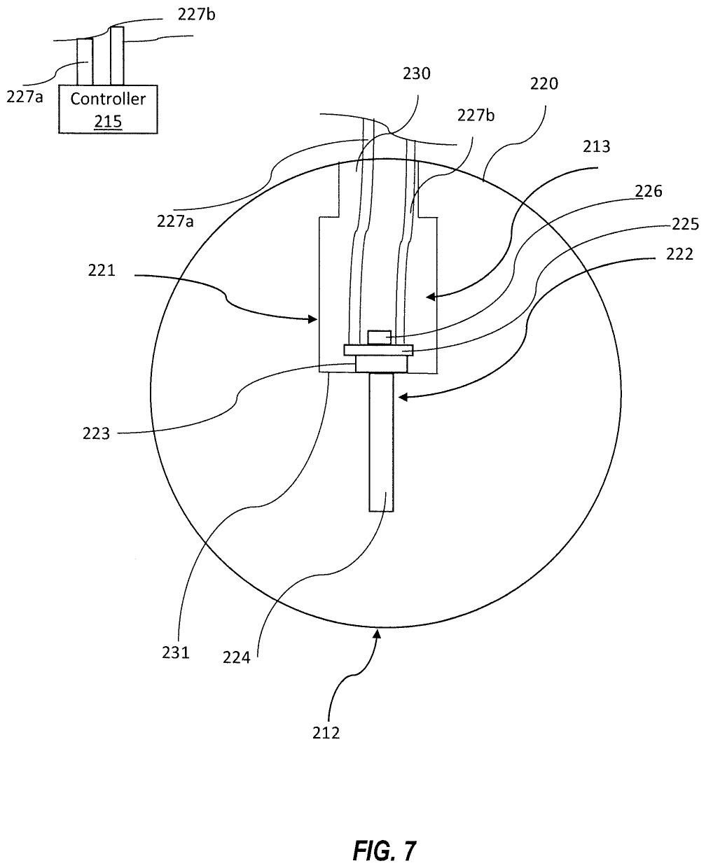

Referring now to FIGS. 6-7, another embodiment of a climbing frame playground structure 210 is now described. It should be appreciated that any features of the above embodiments of the playground structure 10, 110 could be incorporated into the hereinbelow described embodiment, and vice versa.

The climbing frame playground structure 210 illustratively includes a body 211 comprising a plurality of elongate segments 212a-212c coupled together. In the illustrated embodiment, the climbing frame playground structure 210 has a form factor of a jungle-gym. Of course, the features discussed herein can be applied to other park recreation device types, such as those depicted in FIGS. 2A-2H, for example.

The climbing frame playground structure 210 illustratively includes a plurality of piezoelectric sensors 213a-213c, and a plurality of ultrasonic sensors 214a-214c. In some embodiments, the climbing frame playground structure 210 may comprise other sensors, such as image sensors, proximity sensors, pressure sensors, and motion detectors.

Each piezoelectric sensor 213a-213c and ultrasonic sensor 214a-214c is carried by a respective elongate segment 212a-212c of the body 211 and is configured to detect an input on adjacent portions of the respective elongate segment. In particular, the detected input may comprise a touch input of the user or a presence/position of the user. In other words, regardless of the type of sensor used, the purpose is to monitor the user's progress on the body 211. In some embodiments, a subset or all of the plurality of piezoelectric sensors 213a-213c, the plurality of ultrasonic sensors 214a-214c, and the other additional sensors may be recess-mounted within the body 211 (See FIGS. 5 & 7). In other embodiments, a subset or all of the plurality of piezoelectric sensors 213a-213c, the plurality of ultrasonic sensors 214a-214c, and the other additional sensors may be surface-mounted within the body 211. Of course, depending on the placement and application, a combination of recess and surface mount sensors could also be used.

The climbing frame playground structure 210 illustratively comprises an output device 216 (e.g. audio speaker, visual effects projector) configured to generate one or more indicators, such as audio indicators, visual indicators, vibrational indicators, and audiovisual indicators. The climbing frame playground structure 210 illustratively includes a controller 215 coupled to the output device 216 and the plurality of piezoelectric sensors 213a-213c and the plurality of the ultrasonic sensors 214a-214c. The controller 215 is configured to selectively change the indicators based upon the detected input. In one embodiment, the climbing frame playground structure 210 comprises a plurality of output devices 216 (e.g. audio speakers of varying type and placement) spread throughout the recreation area to create a more immersive environment for the user.

In one embodiment, the output device 216 is configured to generate the audio indicators comprising musical instrumental audio indicators (e.g. individual notes or complete musical melodies). That is, as the user interacts with the body 211, the controller 215 maps the scale of the musical instrument to different elongate segments 212a-212c of the body 211. For example, in the illustrated jungle-gym embodiment, as the user climbs from a lower elevation elongate segment 212a-212c to a higher elevation elongate segment, the controller 215 is configured to cause the output device 216 to emit an increasing scale of notes, tending towards a higher frequency, thereby permitting the user to climb the body 211 and climb the musical scale simultaneously.

As perhaps best seen in FIG. 7, each of the plurality of elongate segments 212a-212c illustratively has a substantially circular cross-section, and includes a major surface 220 (i.e. an outer radial surface). Of course, the shape and size of the plurality of elongate segments 212a-212c is exemplary, and other shapes and sizes are readily possible.

Also, each of the plurality of elongate segments 212a-212c illustratively comprises a blind passageway 221 extending inwardly from the major surface 220. The blind passageway 221 illustratively comprises an open first end 230 adjacent the major surface 220, and a closed second end 231 within a respective elongate segment 212a-212c.

The piezoelectric sensor 213 is be carried within the blind passageway 221 adjacent the closed second end 231. The piezoelectric sensor 213 illustratively comprises a fastener 222 comprising a head 223, and a stud 224 (e.g. a threaded stud) extending from the head and into adjacent portions of the respective elongate segment 212a-212c within the blind passageway 221. The piezoelectric sensor 213 illustratively comprises a piezoelectric sensor circuit board 225 coupled to the head 223 of the fastener 222.

In the illustrated embodiment, the fastener 222 comprises a magnetic metallic material (e.g. iron), and the piezoelectric sensor 213 includes a magnetic body 226 (e.g. neodymium magnet). The piezoelectric sensor circuit board 225 is coupled between the magnetic body 226 and the head 223 of the fastener 222. Advantageously, this permits for easy installation of the piezoelectric sensor circuit board 225 into the respective elongate segment 212a-212c within the blind passageway 221. In other embodiments, the piezoelectric sensor circuit board 225 is coupled to the head 223 of the fastener 222 via a mechanical coupling, such as a retention clip attached to the head and coupling the circuit board, or an adhesive layer between the head and the circuit board. Other couplings could be used, but the vibration of the user climbing the respective elongate segment 212a-212c needs to be transmitted to the piezoelectric sensor circuit board 225.

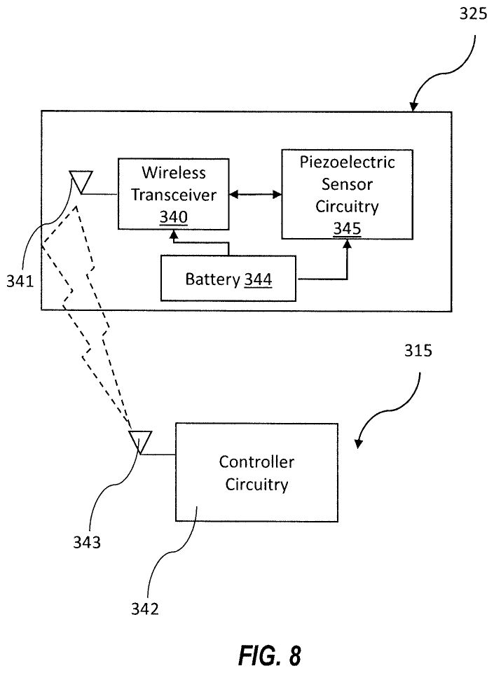

Also, each of the plurality of elongate segments 212a-212c of the body 211 illustratively comprises a longitudinal path 233a-233c coupled to the blind passageways 221. The climbing frame playground structure 210 illustratively comprises a wired connection 227a-227b extending in the longitudinal path 233a-233c and coupled between the piezoelectric sensor circuit board 225 and the controller 215. In some embodiments, the climbing frame playground structure 210 comprises an inline resistor coupled to each of the wired connections 227a-227b to protect the controller 21 from voltage spikes (e.g. generating from electrostatic discharge or a malfunctioning sensor). In other embodiments (FIG. 8), the piezoelectric sensor circuit board 225 includes a wireless interface for communication with the controller 215, and the longitudinal path 233a-233c may be omitted. As will be appreciated, the wireless embodiments are more readily retrofitted onto existing playground structures.

In some embodiments, the longitudinal path 233a-233c comprises a closed passageway within the respective elongate segment 212a-212c. In other embodiments, the longitudinal path 233a-233c comprises an open slot within the respective elongate segment 212a-212c, the open slot facing downwards so as to not affect the user climbing the respective elongate segment. In the open slot embodiments, after installation, the slot may be filled with a foam material to cover the wired connection 227a-227b.

In some embodiments, the controller 215 comprises a micro processing unit, such as an Arduino microcontroller, as available from the Arduino AG of San Jose, Calif. The controller is configured to process the signals from each of the plurality of sensors 213a-213c, 214a-214c. In particular, to avoid misfires of the output indications, the controller 215 is configured to threshold (i.e. minimum signal value) the signals to filter out error signals. If a given sensor generates a set number of error signals exceeding a ceiling value, the controller 215 is configured to disregard the given sensor until maintenance is performed on the climbing frame playground structure 210. Also, to avoid repeated activation of a given sensor (e.g. when an inanimate object is placed over the given sensor), the controller 215 is configured to activate the associated output indication only once, and await activation of another sensor before generating the associated output indication again.

Yet another aspect is directed to a method for making a climbing frame playground structure 210. The method includes positioning a piezoelectric sensor 213 to be carried by a body 211 and configured to detect a touch input on adjacent portions of the body, positioning an output device 216 to generate audio indicators and coupling a controller 215 to the output device and the piezoelectric sensor and configured to selectively change the audio indicators based upon the touch input.

Referring now additionally to FIG. 8, another embodiment of the piezoelectric sensor circuit board 325 is now described. In this embodiment of the piezoelectric sensor circuit board 325, those elements already discussed above with respect to FIGS. 6-7 are incremented by 300 and most require no further discussion herein. This embodiment differs from the previous embodiment in that this piezoelectric sensor circuit board 325 illustratively includes a battery 344, a wireless transceiver 340 coupled to the battery, piezoelectric sensor circuitry 345 coupled to the battery, and an antenna 341 coupled to the wireless transceiver and configured to wirelessly communicate with the controller 315. The controller 315 illustratively comprises a controller circuitry 342, and an antenna 343 coupled thereto for receiving the communications from the piezoelectric sensor circuit board 325. The wireless transceiver 340 may comprise a short range/low power RF transceiver, such as a Bluetooth transceiver, ZigBee or a WiFi transceiver (IEEE 802.11x).

Many modifications and other embodiments of the present disclosure will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

That which is claimed is:

1. A playground structure comprising:
a body;
a piezoelectric sensor carried by said body and configured to detect a touch input on adjacent portions of said body;
an output device configured to generate audio indicators; and
a controller coupled to said output device and said piezoelectric sensor and configured to selectively change the audio indicators based upon the touch input.

2. The playground structure of claim 1 wherein said body includes a major surface, and a blind passageway extending inwardly from said major surface; and wherein said piezoelectric sensor is carried within said blind passageway.

3. The playground structure of claim 2 wherein said piezoelectric sensor comprises:
a fastener comprising a head, and a stud extending from said head and into said body within said blind passageway; and
a piezoelectric sensor circuit board coupled to said head of said fastener.

4. The playground structure of claim 3 wherein said fastener comprises a metallic material; and wherein said piezoelectric sensor comprises a magnetic body, said piezoelectric sensor circuit board being between said magnetic body and said head of said fastener.

5. The playground structure of claim 3 wherein said body comprises a longitudinal path coupled to said blind passageway; and further comprising a wired connection extending in said longitudinal path and coupled between said piezoelectric sensor circuit board and said controller.

6. The playground structure of claim 3 wherein said piezoelectric sensor circuit board comprises a wireless transceiver configured to wirelessly communicate with said controller.

7. The playground structure of claim 1 wherein said output device comprises an audiovisual output device configured to generate audiovisual indicators; and wherein said controller is configured to change the audiovisual indicators based upon the touch input.

8. The playground structure of claim 1 wherein said output device is configured to generate the audio indicators comprising musical instrumental audio indicators.

9. The playground structure of claim 1 further comprising an ultrasonic sensor carried by said body, coupled to said controller, and configured to detect the touch input on the adjacent portions of said body.

10. A climbing frame playground structure comprising:
a body comprising a plurality of elongate segments coupled together;
a plurality of piezoelectric sensors, each piezoelectric sensor carried by a respective elongate segment of said body and configured to detect a touch input on adjacent portions of the respective elongate segment;
an output device configured to generate audio indicators; and
a controller coupled to said output device and said plurality of piezoelectric sensors and configured to selectively change the audio indicators based upon the touch input.

11. The climbing frame playground structure of claim 10 wherein each elongate segment includes a major surface, and a blind passageway extending inwardly from said major surface; and wherein a respective piezoelectric sensor is carried within said blind passageway.

12. The climbing frame playground structure of claim 11 wherein the respective piezoelectric sensor comprises:
a fastener comprising a head, and a stud extending from said head and into said body within said blind passageway; and
a piezoelectric sensor circuit board coupled to said head of said fastener.

13. The climbing frame playground structure of claim 12 wherein said fastener comprises a metallic material; and wherein the respective piezoelectric sensor comprises a magnetic body, said piezoelectric sensor circuit board being between said magnetic body and said head of said fastener.

14. The climbing frame playground structure of claim 12 wherein each elongate segment includes a longitudinal path coupled to said blind passageway; and further comprising a wired connection extending in said longitudinal path and coupled between said piezoelectric sensor circuit board and said controller.

15. The climbing frame playground structure of claim 12 wherein said piezoelectric sensor circuit board comprises a wireless transceiver configured to wirelessly communicate with said controller.

16. The climbing frame playground structure of claim 10 wherein said output device comprises an audiovisual output device configured to generate audiovisual indicators; and wherein said controller is configured to change the audiovisual indicators based upon the touch input.

17. A method for making a playground structure comprising:
positioning a piezoelectric sensor to be carried by a body and configured to detect a touch input on adjacent portions of the body;
positioning an output device to generate audio indicators; and
coupling a controller to the output device and the piezoelectric sensor and configured to selectively change the audio indicators based upon the touch input.

18. The method of claim 17 wherein the body includes a major surface, and a blind passageway extending inwardly from the major surface; and wherein the piezoelectric sensor is carried within the blind passageway.

19. The method of claim 18 wherein the piezoelectric sensor comprises:
a fastener comprising a head, and a stud extending from the head and into the body within the blind passageway; and
a piezoelectric sensor circuit board coupled to the head of the fastener.

20. The method of claim 19 wherein the fastener comprises a metallic material; and wherein the piezoelectric sensor comprises a magnetic body, the piezoelectric sensor circuit board being between the magnetic body and the head of the fastener.
